(19) United States
(12) Patent Application Publication
(10) Pub. No.: US 2015/0305139 A1
(43) Pub. Date: Oct. 22, 2015

(54) FLEXIBLE PRINT CIRCUIT BOARD AND DEVICE PROVIDED WITH THE SAME

(71) Applicant: Nidec Copal Corporation, Tokyo (JP)

(72) Inventors: Shunichi NAGANO, Tokyo (JP); Shigemi TAKAHASHI, Tokyo (JP)

(73) Assignee: Nidec Copal Corporation, Tokyo (JP)

(21) Appl. No.: 14/424,140

(22) PCT Filed: Aug. 27, 2013
(86) PCT No.: PCT/JP2013/072810

§ 371 Date: Feb. 26, 2015

(30) Foreign Application Priority Data
Aug. 31, 2012 (JP) 2012-206231
Mar. 18, 2013 (JP) 2013-055716

(51) Int. Cl. H05K 1/02; H05K 1/09

(52) U.S. Cl. CPC H05K 1/028; H05K 1/09; H05K 2201/0326; H05K 2201/0355

(57) ABSTRACT

A flexible print circuit board has a hole into which a pillar-shaped projection protruding from a base body of a device is fitted. The hole includes at least one first edge part formed to have a convex shape toward the center of the hole, and second edge parts provided on the both sides of the first edge part respectively and formed to have a concave shape toward the center of the hole.

### CROSS-REFERENCE TO RELATED APPLICATION

This is a U.S. national phase application under 35 U.S.C. § 371 of International Patent Application No. PCT/JP2013/072810, filed on Aug. 27, 2013, and claims benefit of priority to Japanese Patent Application Nos. JP 2012-206231, filed on Aug. 31, 2012, and JP 2013-055716, filed on Mar. 18, 2013. The International Application was published on Mar. 6, 2014, as International Publication No. WO 2014/034637 under PCT Article 21(2). The entire contents of these Applications are hereby incorporated herein by reference.

### TECHNICAL FIELD

This invention relates to a flexible print circuit board capable of being fitted to a pillar-shaped projection that is erectly provided for various types of devices with the edge of a hole deformed and to a device provided with the flexible print circuit board.

### BACKGROUND

Unless there is a special reason, it is usual to use a flexible print circuit board for wiring for various types of small devices, recently. And, it has been known that methods of keeping flexible print circuit boards in stable states without wobbling relative to devices (flexible print circuit board may be fitted to the bodies of the devices or to parts that are fitted directly or indirectly to the bodies of the devices) include methods of fixing flexible print circuit boards to devices with screws, caulking, soldering, and double-sided tapes. And, for example, a method disclosed in the following Japanese Patent Application Publication TOKUKAI No. 2003-295252 (“the JP '252”) has been known as one of these methods.

And, the method disclosed in the JP '252 is a method in which: a pillar-shaped projection (pin) is erectly provided on a device; a hole the diameter of which is smaller than that of the pillar-shaped projection is provided on a flexible print circuit board; and the pillar-shaped projection is fitted into the hole while the hole is widened by deforming a portion adjacent to the edge of the hole (press-fitting method). The present invention relates to a flexible print circuit board favorable for adopting a method like the method disclosed in the JP '252 and to a device provided with the same.

In the case of the press-fitting method disclosed in the JP '252, the hole provided for the flexible print circuit board, which is as described above, is shaped like a circle, and the diameter of the hole is smaller than that of the pillar-shaped projection. And, as known publically, base bodies of flexible print circuit boards are made of polyimide, so that flexible print circuit boards are flexible. Accordingly, when the pillar-shaped projection is fitted into the hole, the portion adjacent to the edge of the hole is stretched to be deformed so that the portion is warped to the top end side of the pillar-shaped projection while the hole is being widened.

Now, even in the case where a flexible print circuit board is fitted to a device in such a press-fitting method, there may be the necessity that a flexible print circuit board should be again fitted to a projection of a device after the flexible print circuit board is removed away from the projection of the device once, for example, in the middle of assembly of the device. However, when the flexible print circuit board is fitted to the projection of the device for the first time or removed away from the projection of the device afterward, a crack occurs in the edge of a hole because of the relation between machining accuracy of the projection and machining accuracy of the hole, so that the occurrence of the crack may be a hindrance to second fitting of the flexible print circuit board to the device. Also, the portion adjacent to the edge of the hole is subjected to plastic deformation when the flexible print circuit board is fitted to the device for the first time, so that it may be inevitably impossible to sufficiently secure the stability of fitting of the flexible print circuit board when the flexible print circuit board is again fitted to the device after the flexible print circuit board is removed away from the device once.

The present invention is made in order to solve such problems. An aspect of the present invention is to offer: a flexible print circuit board in which the shape of a hole provided for the flexible print circuit board is contrived so that the edge of the hole is not damaged even though a pillar-shaped projection erectly provided on the device side is fitted into the hole while the portion adjacent to the edge of the hole is being deformed and it is possible to sufficiently secure the stability of fitting of the flexible print circuit board even though the pillar-shaped projection is repeatedly removed away from the hole or repeatedly fitted into the hole; and a device provided with the same.

### SUMMARY

A flexible print circuit board according to the present invention which includes a hole into which a pillar-shaped projection of a device is fitted, the hole includes: at least one first edge part which is formed to have a convex shape toward the center of the hole; and second edge parts which are provided on the both sides of the first edge part respectively and have concave shapes toward the center of the hole.

In this case, when the flexible print circuit board is made to have a structure in which the first and second edge parts of the edge of the hole are formed in succession while the first edge parts are alternating with the second edge parts, it becomes easy to align the center of the pillar-shaped projection with the center of the hole. Also, when at least the second edge parts of the first and second edge parts are formed to be shaped like a curve, such a flexible print circuit board has the advantage of having good endurance.

Also, in a flexible print circuit board according to the present invention, a copper foil pattern is formed at a predetermined distance from the edge of the hole while the hole is partially or wholly surrounded by the copper foil pattern, so that the strength of the hole in fitting the pillar-shaped projection into the hole is increased, and the copper foil pattern cannot break easily even when the flexible print circuit board is fitted to or removed away from a device. Also, even when the copper foil pattern is formed adjacently to at least a part of the second edge parts, the same effect as described above can be obtained.

Also, in a flexible print circuit board according to the present invention, a copper foil pattern including a second hole is formed on a surface of the flexible print circuit board through which the flexible print circuit board is fitted to a base body of the device, and the second hole has approximately the same shape and approximately the same size as the hole of the flexible print circuit board does.

Also, a flexible print circuit board according to the present invention is characterized in that a head part of a support shaft which is erectly provided for the base body of the device and to which a rotary unit is rotatably fitted is fitted into the hole.

In addition, a device according to the present invention is characterized in that the device includes a flexible print circuit board having at least one of the above-described structures.

According to the present invention, a hole formed on a flexible print circuit board includes: at least one first edge part convex toward the center of the hole; and second edge parts provided on the both sides of the first edge part respectively and concave toward the center of the hole, so that there is no fear that the edge of the hole is broken even though a pillar-shaped projection is fitted into the hole while a portion adjacent to the first edge part is being deformed. Also, even though fitting the pillar-shaped projection into the hole again after removing the pillar-shaped projection away from the hole once is repeated, there occurs no impediment to fitting of the flexible print circuit board, and there occurs no circumstance where it is inevitably impossible to secure original strength for fitting the pillar-shaped projection into the hole. Also, according to the present invention, the flexible print circuit board is provided with a cupper foil pattern capable of discharging static electricity that occurs in the device through the pillar-shaped projection, so that it is possible to effectively remove a failure of the device due to static electricity.

### BRIEF DESCRIPTION OF DRAWINGS

FIG. 1 is a front view showing Example according to the present invention applied to a focal plane shutter for cameras.

FIG. 2 is a front view showing a state in which only a block of a setting drive device removed away from a shutter unit is rotated by 90 degrees, while the approximately one-third of the right-side part of FIG. 1 is being omitted.

FIG. 3 is a plane view showing a flexible print circuit board used for the Example.

FIG. 4 is an enlarged plane view showing a portion around one of holes which are formed on the flexible print circuit board of the Example.

FIG. 5 is a side view showing a state in which a pillar-shaped projection erectly provided for the block of the setting drive device is fitted into the hole shown in FIG. 4.

FIG. 6 is an enlarged plane view showing a portion around another hole formed on the flexible print circuit board of the Example.

FIG. 7 is a plane view showing an example of variations of a portion around the hole shown in FIG. 4.

FIG. 8 is a plane view showing a first example of variations of the shape of the hole shown in FIG. 4 and a first example of variations of the portion around the hole shown in FIG. 4.

FIG. 9 is a plane view showing a second example of variations of the shape of the hole shown in FIG. 4 and a second example of variations of the portion around the hole shown in FIG. 4.

FIG. 10 is a perspective view showing Another Example according to the present invention applied to the focal plane shutter for cameras shown in FIG. 1.

FIG. 11 is a partial sectional view showing a main part of the structure of the Another Example.

FIG. 12 is a plane view showing one example of a flexible print circuit board used for the Another Example.

FIG. 13 is an enlarged plane view showing a portion around one of holes which are formed on the flexible print circuit board of the Another Example.

FIG. 14 is a plane view showing an example of variations of the shape of the hole shown in FIG. 13.

FIG. 15 is a plane view showing an example of variations of the shape of the hole shown in FIG. 13 and an example of variations of the portion around the hole shown in FIG. 13.

FIG. 16 is a front view showing a flexible print circuit board of Yet Another Example according to the present invention.

FIG. 17 is a sectional view showing one example of a state in which a pillar-shaped projection is fitted to the flexible print circuit board of the Yet Another Example.

FIG. 18 is a plane view showing a portion around one of holes which are formed on the flexible print circuit board of the Yet Another Example.

FIG. 19 is a plane view showing a first example of variations of the shape of the hole shown in FIG. 18 and a first example of variations of the portion around the hole shown in FIG. 18.

FIG. 20 is a plane view showing a second example of variations of the shape of the hole shown in FIG. 18 and a second example of variations of the portion around the hole shown in FIG. 18.

FIG. 21 is a front view showing Further Example according to the present invention applied to a diaphragm for cameras.

### DETAILED DESCRIPTION

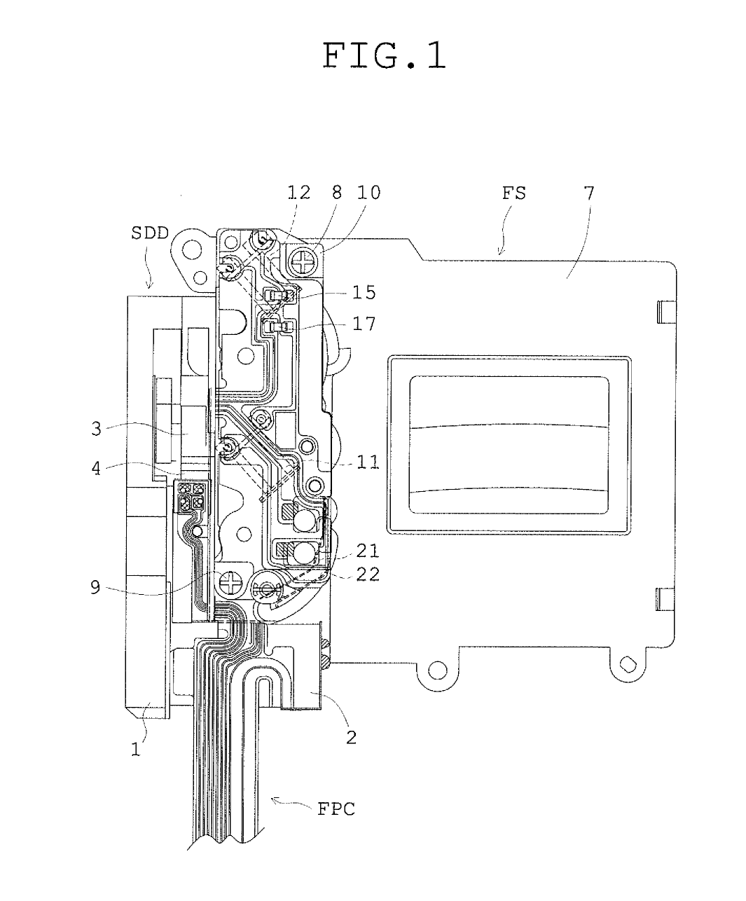

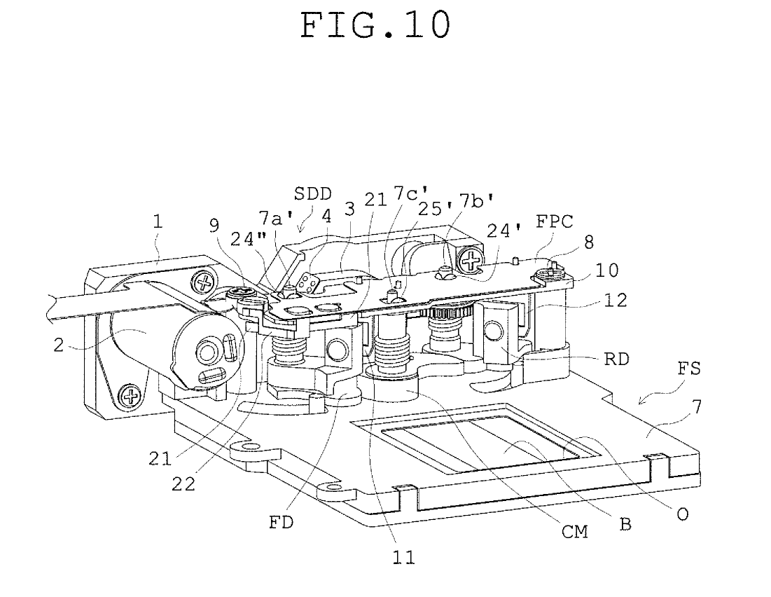

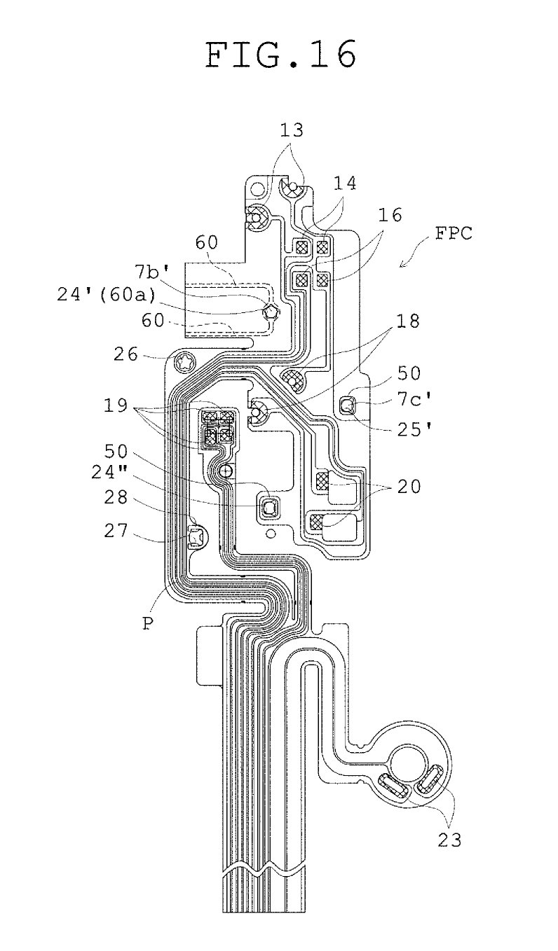

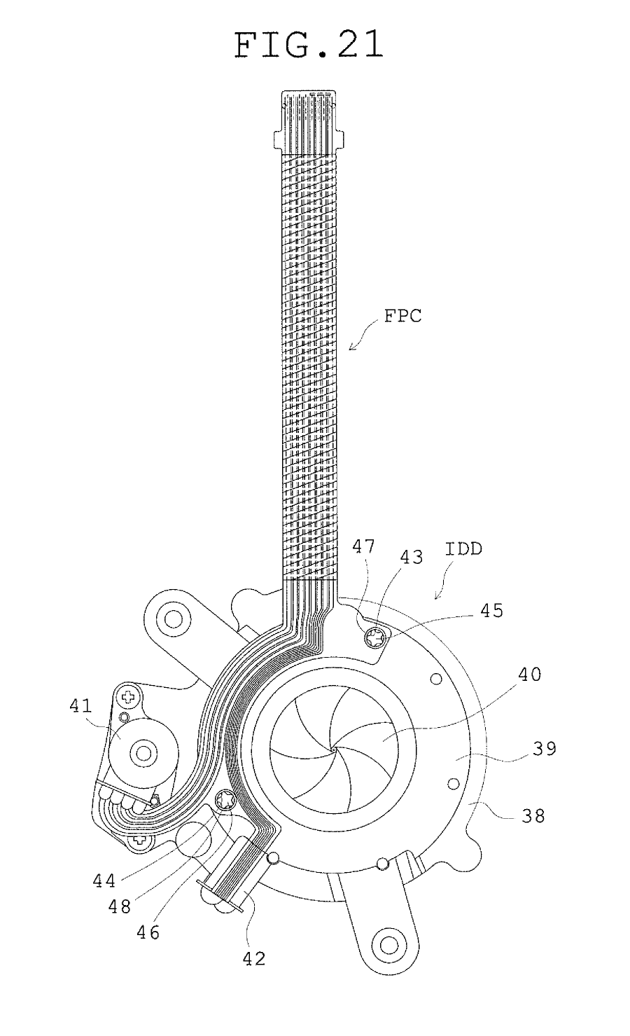

Four examples of the present invention shown in the drawings are explained. Example, Another Example and Yet Another Example of them are applied to focal plane shutters for cameras, and Further Example is applied to a blade-driving device like a diaphragm for cameras. Flexible print circuit boards according to the present invention are not limited to the application to such devices related to cameras but can be applied to all devices that require fitting of a flexible print circuit board. FIGS. 1 to 9 are used for explaining the Example, FIGS. 10 to 15 are used for explaining the Another Example, FIGS. 16 to 20 are used for explaining the Yet Another Example, and FIG. 21 are used for explaining the Further Example.

### Example

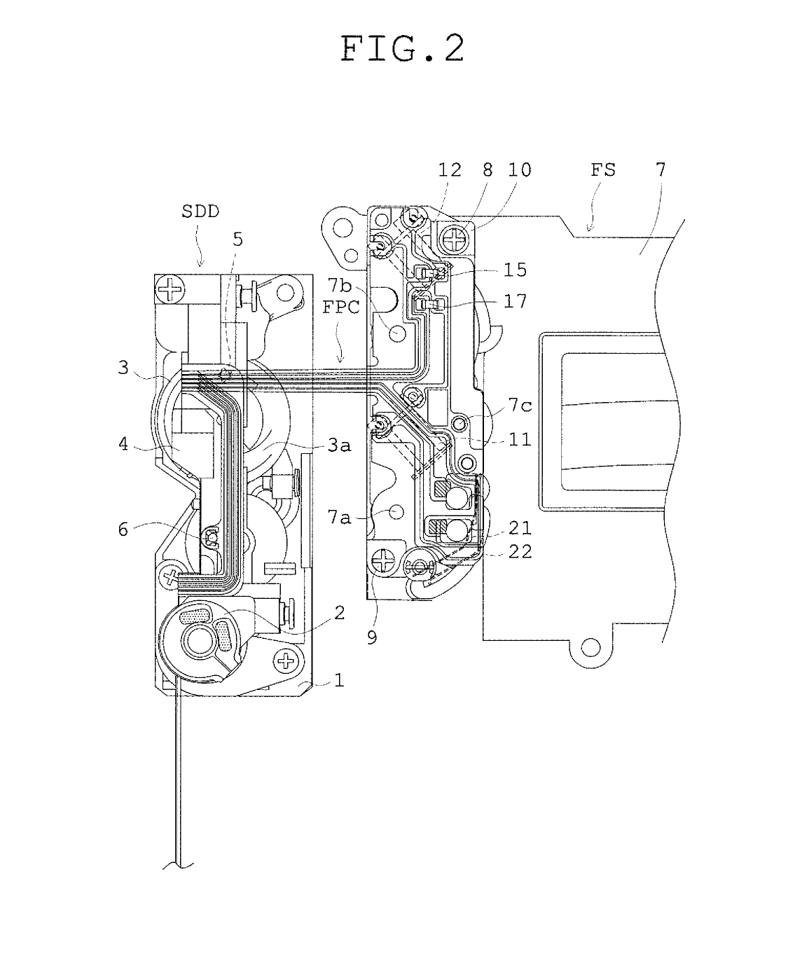

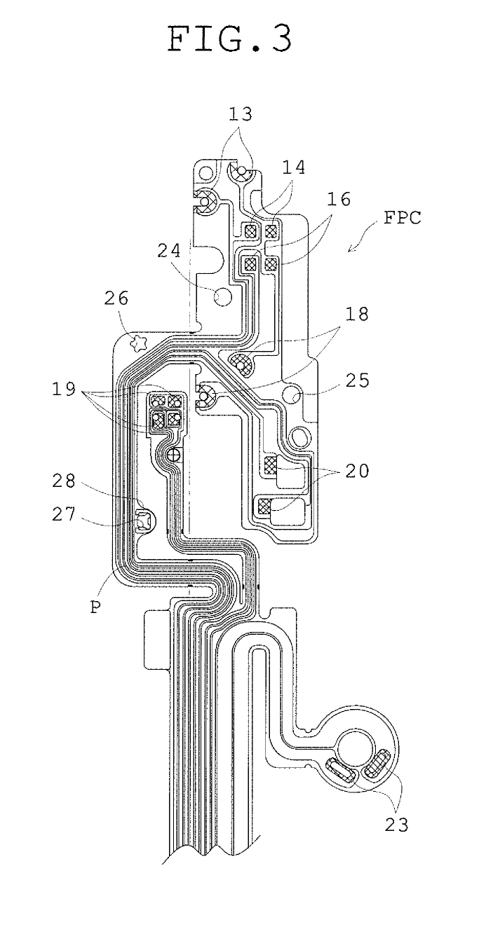

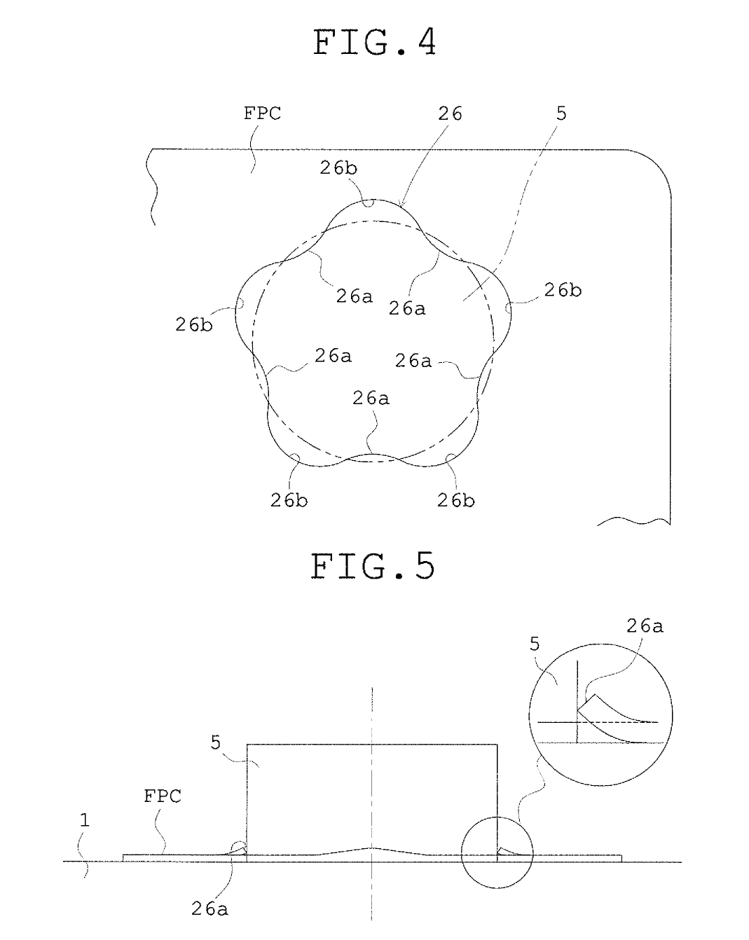

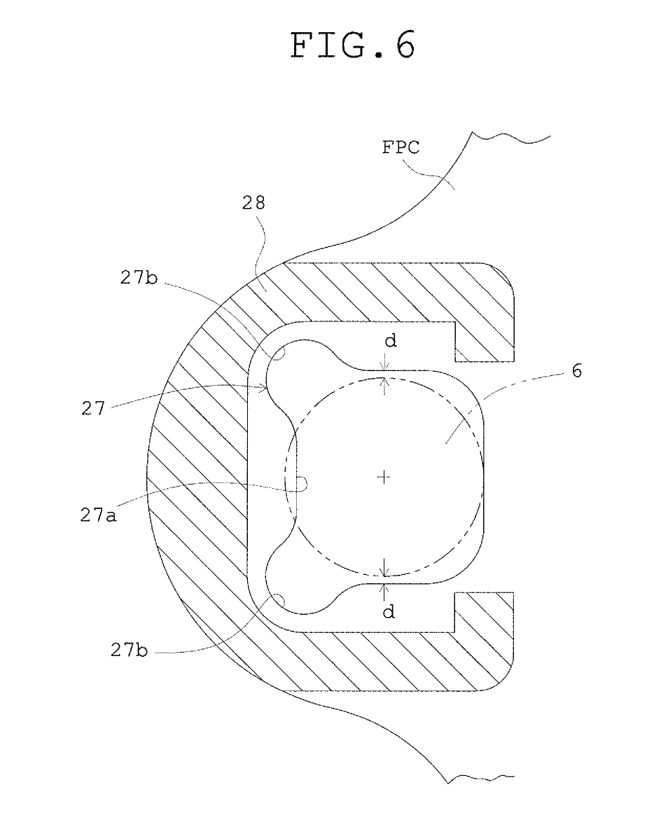

The present example is the case where the present invention is applied to a focal plane shutter for cameras. And, FIG. 1 is a front view showing a unit of the focal plane shutter, FIG. 2 is a front view showing a state in which only a block of a setting drive device is removed away from the shutter unit to be rotated by 90 degrees on the left side of FIG. 2, while the approximately one-third of the right side part of the shutter unit shown in FIG. 1 is being omitted. FIG. 3 is a plane view showing a flexible print circuit board used for the shutter unit. Also, FIG. 4 is a plane view showing a portion around one of holes which are formed on the flexible print circuit board in the present example, with the portion enlarged. FIG. 5 is a side view showing a state in which a pillar-shaped projection erectly provided for the setting drive device is fitted into the hole shown in FIG. 4. FIG. 6 is a plane view showing a portion around another hole of the holes formed on the flexible print circuit board, with the portion enlarged.

First, the constitution of this focal plane shutter FS is explained. Needless to say, the present invention is made not for the constitution intrinsic to the focal plane shutter itself but for the constitution of fitting of the flexible print circuit board to the pillar-shaped projection that is erectly provided on the focal plane shutter unit. Accordingly, only the summary of the constitution intrinsic to the focal plane shutter is explained by referring to a publically-known patent literature or the like.

The shutter unit shown in FIG. 1 includes a setting drive device provided with a DC motor, as disclosed in Japanese Patent TOKUKAI No. 2003-107559 for example. In the present example, the setting drive device SDD is assembled from components of the setting drive device as a block and fixed to the focal plane shutter FS as shown in FIG. 2.

First, the summary of the constitution of the setting drive device SDD is explained mainly using FIG. 2. A DC motor 2, a gear 3 which is rotated through a gear having no numeral reference, and a sensor 4 are fitted to a base body 1 of the setting drive device SDD. And, two pillar-shaped projections 5 and 6 are provided on the base body 1 with the two pillar-shaped projections 5 and 6 erect. The two pillar-shaped projections 5 and 6 are explained below in detail using FIGS. 4 to 6.

Also, a rotation of the gear 3 is transmitted to a transmission mechanism by a cam 3a provided on its lateral side, the transmission mechanism being provided for the focal plane shutter FS and being not shown in the drawings. After the gear 3 makes a turn, a setting unit not shown in the drawings is rotated back and forth between its initial position and its setting position, only one time, through the transmission mechanism.

Also, the sensor 4 is a publically-known photo-interrupter including four terminal pins. The sensor 4 is formed to detect two rotation positions of the gear 3 so as to indirectly detect the initial position of the setting unit and the setting position of the setting unit to stop a rotation of the DC motor 2. And, the four terminal pins of the sensor 4 are made to face toward the left lower side of FIG. 2 and are inserted into holes that are formed on below-described lands of the flexible print circuit board FPC, respectively.

As known publically, two drive units and the setting unit are arranged between a shutter base plate 7 and a support plate 10, the support plate 10 being fitted to the shutter base plate 7 with two screws 8 and 9 while being at a predetermined distance from the shutter base plate 7. Also, two publically-known electromagnets 11 and 12 are fitted on the shutter-base-plate-7 side of the support plate 10. However, only bobbins of the electromagnets 11 and 12 around which coils are wound respectively are shown with broken line in FIGS. 1 and 2. And, the below-described flexible print circuit board FPC (which is called “FPC” hereinafter) is fitted to the support plate 10 while the flexible print circuit board FPC is being put on the support plate 10. Besides, the support plate 10 of the present example practically consists of two plates of first and second support plates, the first support plate is made of metal, the second support plate is made of synthetic resin, and the first support plate is put on the second support plate while being located on the shutter-base-plate-7 side, or on the side of the second support plate opposite to the flexible-print-circuit-board-FPC side, although this matter is not clearly illustrated.

As shown in FIG. 2, the top end of a shaft 7a which is erectly provided on the shutter base plate 7 and to which the above-described first blade-driving unit is rotatably fitted is inserted into a hole of the support plate 10. And, the top end of a shaft 7b to which a second blade-driving unit is rotatably fitted is inserted into holes of the support plate 10 and the FPC. Also, the top end of a shaft 7c which is erectly provided on the shutter base plate 7 and to which the setting unit is rotatably fitted is inserted into holes of the support plate 10 and the FPC. Two terminal pins provided for each of the electromagnets 11 and 12 protrude toward this side of the FPC. Besides, the numeral references of the shafts 7a, 7b, and 7c are omitted in FIG. 1.

Next, the constitution of the FPC is explained mainly using FIG. 3. First, the lands provided for the FPC are explained in descending order from the upper side of FIG. 3. Two lands 13 are connected with the terminal pins of the electromagnet 12 shown in FIGS. 1 and 2, respectively, with soldering. Two lands 14 are connected with a chip part, for example, like a condenser 15 shown in FIGS. 1 and 2. Two lands 16 are connected with a chip part, for example, like a condenser 17 shown in FIGS. 1 and 2. Two lands 18 are connected with the terminal pins of the electromagnets 11 shown in FIGS. 1 and 2, respectively.

Also, four lands 19 are connected with the four terminal pins of the sensor 4 shown in FIGS. 1 and 2, respectively, with soldering. Two lands 20 are connected with one ends of a pair of publically-known contact piece elements 21 and 22 for flashlight which are shown in FIGS. 1 and 2, respectively. Two lands 23 are connected with the two terminal pins which are provided for the DC motor 2 shown in FIGS. 1 and 2, respectively. Besides, the numeral references of these lands shown in FIG. 3 are omitted in FIGS. 1 and 2.

The FPC is provided with holes 24 and 25 into which the top ends of the shafts 7b and 7c of the shutter base plate 7 are inserted respectively. In addition, the FPC is provided with: a hole 26 into which the pillar-shaped projection 5 erectly provided on the setting drive device SDD is fitted; and a hole 27 into which the pillar-shaped projection 6 is fitted. The holes 24 and 25 are shaped like a circle. On the other hand, the holes 26 and 27 have special shapes. In particular, a cupper foil pattern 28 which is difference from a wiring (circuit) pattern P is formed around the hole 27, and the cupper foil pattern 28 is used for reinforcing a portion around the hole 27. Accordingly, the shapes of the two holes 26 and 27 having special shapes, the shapes of the respective portions around the holes 26 and 27, the constitution of fitting of the pillar-shaped projection 5 into the hole 26, and the constitution of fitting of the pillar-shaped projection 6 into the hole 27 are explained below in detail using FIGS. 4 to 6. Accordingly, the numeral references of the holes 26 and 27 and the copper foil pattern 28 are omitted in FIG. 1.

Besides, publically-known FPCs are provided with the cupper foil patter 28 between the base body of each FPC and a cover lay, together with the wiring pattern P. These holes 26 and 27 may be formed on a portion of the base body on which the cover lay is put. Alternatively, the holes 26 and 27 may be formed on only a portion of the base body on which the cover lay is not put. In the case where a copper foil pattern for reinforcement is formed on a portion around a hole, like the hole 27 in the present example, it is preferred that the copper foil pattern is covered with the cover lay.

Next, methods of fitting the FPC shown in FIG. 3 to the setting drive device SDD and to the focal plane shutter FS are explained. Besides, as seen by comparing FIG. 1 with FIG. 2, the FPC shown in FIG. 1 is fitted to the setting drive unit SDD while a horizontally U-shaped part of the FPC shown on the left side of the long dashed short dashed line in FIG. 3 is being bent by 90 degrees to the back of the sheet showing FIG. 3.

First, the FPC is soldered to six places of the setting drive device SDD that is assembled as a block. If the FPC is unstable, it becomes extremely difficult to solder the FPC to the SDD. Accordingly, before the FPC is soldered to the SDD, the FPC shown in FIG. 3 is rotated by 180 degrees horizontally in FIG. 3 to be reversed, and then the pillar-shaped projections 5 and 6 erectly provided for the base body 1 are fitted into the two holes 26 and 27 of the reversed FPC, respectively, in a state of the setting drive device SDD shown in FIG. 2.

The FPC is positioned relative to the setting drive device SDD to be in a stable state, by this process, so that it is possible to easily solder the FPC to the setting drive device SDD.

Next, the FPC is bent by 90 degrees along the long dashed short dashed line shown in FIG. 3 as described above, and then the four terminal pins of the sensor 4 are fitted into the holes provided for the four lands 19, respectively, to be soldered. Also, a portion of the FPC which is located on the right side in the lower side of FIG. 3 is subjected to such a process as: its band-shaped portion is wound around only about half of the circumference surface of the DC motor 2; its circle-shaped portion is bent by 90 degrees; and then the two terminal pins provided for the DC motor 2 are fitted into elongate holes provided for the two lands 23, respectively, to be soldered.

Next, the FPC is fitted to the focal plane shutter FS. In the present example, after the setting drive device SDD is fitted to the focal plane shutter FS in advance, the FPC is soldered to the focal plane shutter FS. It is also possible to fit the setting drive device SDD to the focal plane shutter FS after the FPC is soldered to the focal plane shutter FS. It is preferred that the condensers 15 and 17 are soldered to the FPC before the FPC is soldered to the setting drive device SDD. Alternatively, the condensers 15 and 17 may be soldered to the FPC after the FPC is soldered to the focal plane shutter FS.

Now, as in the present example, in the case where the FPC is soldered to the focal plane shutter FS after the setting drive device SDD is fitted to the focal plane shutter FS in a proper method in advance, the shafts 7b and 7c of the shutter base plate 7 are first fitted into the holes 24 and 25 respectively, the two terminal pins of each of the electromagnets 12 and 11 are loosely fitted into the holes or grooves provided for each of the two lands 13 and the two lands 18, respectively, and then the FPC is soldered to the focal plane shutter FS. On the other hand, the one ends of the two contact piece elements 21 and 22 which have been fitted to the support plate 10 are soldered to the two lands 20 respectively.

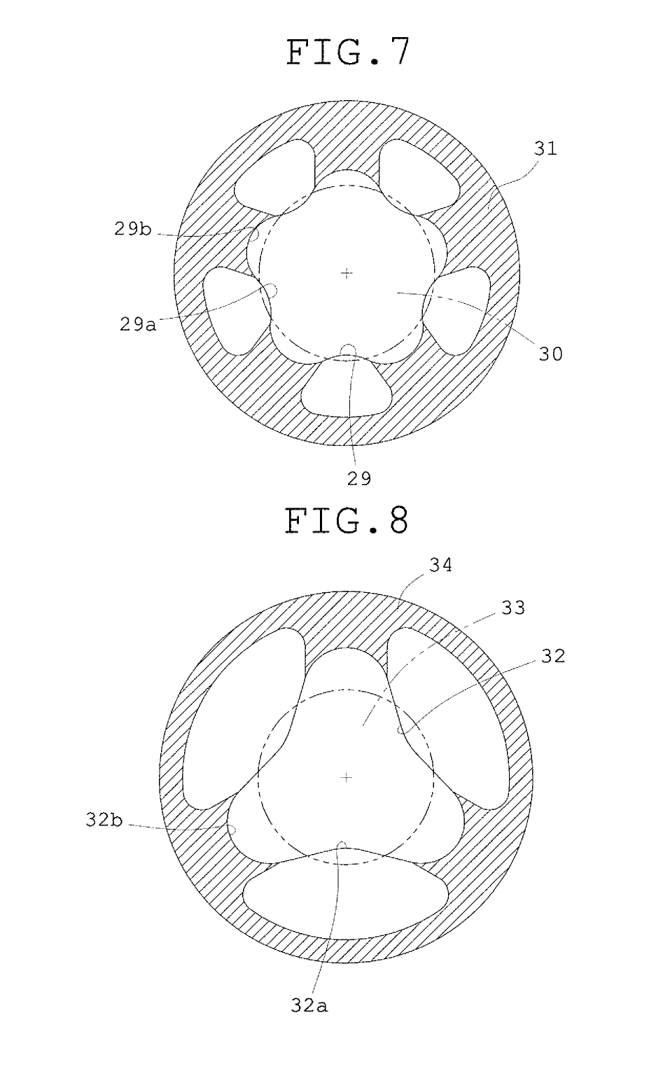

The FPC of the present example is soldered to the setting drive device SDD and the focal plane shutter FS in such a manner. The relations between the pillar-shaped projections 5 and 6 erectly provided for the base body 1 of the setting drive device SDD and the holes 26 and 27 provided for the FPC are explained using FIGS. 4 to 6, and examples of variations of these holes are explained using FIGS. 7 to 9.

First, the shape of the hole 26 provided for the FPC and the relation between the hole 26 and the pillar-shaped projection 5 erectly provided for the base body 1 of the setting drive device SDD are explained using FIGS. 4 and 5. FIG. 4 is an enlarged plane view showing a portion around the hole 26 into which the pillar-shaped projection 5 is not fitted yet, and the pillar-shaped projection 5 is shown with long dashed double-short dashed line.

As shown in FIG. 4, the edge of the hole 26 for the present example is composed of: five first edge parts 26a formed to be a convex curve toward the center of the hole 26; and five second edge parts 26b formed to be a concave curve toward the center of the hole 26, the five first edge parts 26a and the five second edge parts 26b being formed in succession while the five first edge parts 26a are alternating with the five second edge parts 26b. When the top end of the pillar-shaped projection 5 is made to meet the hole 26 in order to fit the pillar-shaped projection 5 into the hole 26, portions adjacent to the first edge parts 26a overlap with the pillar-shaped projection 5. In this state, a space is formed between each of the second edge parts 26b and the pillar-shaped projection 5. And, the hole 26 is formed in such a way that the area of the spaces formed between the second edge parts 26b and the pillar-shaped projection 5 is larger than that of the portions adjacent to the first edge parts 26a overlapping with the pillar-shaped projection 5.

The hole 26 is positioned relative to the pillar-shaped projection 5 as shown in FIG. 4, and then the portion around the hole 26 is pushed toward the base body 1 by a tool or a finger, so that the pillar-shaped projection 5 is fitted into the hole 26 while the first edge parts 26a are being bent toward the top end of the pillar-shaped projection 5. And, the portion around the hole 26 is pushed up to the base body to come into contact with the base body 1. FIG. 5 shows such a state.

Even though the tool or the finger is removed away from the portion around the hole 26, the pillar-shaped projection 5 cannot be easily separated from the hole 26 due to friction force and restoring force between the five first edge parts 26a and the pillar-shaped projection 5. However, in the case where the FPC is separated from the setting drive device SDD because of repair, a tool is inserted between the FPC and the base body 1, and then the FPC is pushed up toward the top end of the pillar-shaped projection 5 through the tool, so that the FPC can be relatively easily separated from the setting drive device SDD. In the present example, when the pillar-shaped projection 5 is fitted into the hole 26, the portions adjacent to the first edge parts 26a are merely bent. Accordingly, as long as the FPC is fitted to the base body 1 in a normal manner, there is neither fear that that plastic deformation occurs nor fear that a crack occurs in the edge of the hole 26.

Next, the shape of the hole 27 provided for the FPC and the relation between the hole 27 and the pillar-shaped projection 6 erectly provided for the base body 1 of the setting drive device SDD are explained using FIG. 6. FIG. 6 is an enlarged plane view showing the portion around the hole 27 into which the pillar-shaped projection 6 is not inserted yet, and the pillar-shaped projection 6 is shown with long dashed double-short dashed line.

As shown in FIG. 6, a part of the edge of the hole 27 for the present example includes: one first edge part 27a formed to be convex toward the center of the hole 27; and two second edge parts 27b formed to be a concave curve toward the center of the hole 27 with the two second edge parts 27b located on the both sides of the first edge part 27a respectively. When the top end of the pillar-shaped projection 6 is made to meet the hole 27 in order to fit the pillar-shaped projection 6 into the hole 27, only one portion adjacent to the first edge part 27a overlaps with the pillar-shaped projection 6, and the portions adjacent to the other edge parts other than the first edge part 27a do not overlap with the pillar-shaped projection 6. The area of spaces formed between the second edge parts 27b and the pillar-shaped projection 6 is larger than that of the portion adjacent to the edge of the hole 27 which overlaps with the pillar-shaped projection 6. The hole 27 is formed to have spaces d between an edge part of the hole 27 on the upper side of FIG. 6 and the pillar-shaped projection 6 and between an edge part of the hole 27 on the lower side of FIG. 6 and the pillar-shaped projection 6. As a result, even though the center of the hole 27 is somewhat out of the center of the pillar-shaped projection 6 due to some cause when the center of the hole 26 is made to align with the center of the pillar-shaped projection 5, the pillar-shaped projection 6 can be fitted into the hole 27.

Accordingly, the hole 27 having such a shape is positioned relative to the pillar-shaped projection 6 as shown in FIG. 6, and then a portion around the hole 27 is pushed toward the base body 1 by a tool or a finger, so that the pillar-shaped projection 6 is fitted into the hole 27 while the only one first edge part 27a provided for the edge of the hole 27 is being warped toward the top end of the pillar-shaped projection 6. The pillar-shaped projection 6 cannot be easily separated from the hole 27 due to friction force between the first edge part 27a and the pillar-shaped projection 6.

Also, in the case of repair, it is possible to relatively easily separate the pillar-shaped projection 6 from the hole 27. And, even though the pillar-shaped projection 6 is repeatedly fitted into or repeatedly separated from the hole 27, there is neither fear that plastic deformation occurs nor fear that a crack occurs in the edge of the hole 27. In addition, a copper foil pattern 28 is formed on the portion around the hole 27 at a predetermined distance from the hole 27 while, in particular, the one first edge part 27a and the two second edge parts 27b are being surrounded by the copper foil pattern 28. As a result, the portion around the first edge part 27a which is formed between the copper foil pattern 28 and the hole 27 to be bent becomes narrow, so that large fiction force between the first edge part 27a and the pillar-shaped projection 6 can be obtained, and it becomes difficult to damage the first edge part 27a and the second edge parts 27b because the portion adjacent to the first edge part 27a is bent.

Besides, although the copper foil pattern 28 is formed on the portion around the hole 27 in the above-described manner in the present example, there is a case where a copper foil pattern is not necessary formed on such a portion depending on a position at which the hole is formed or the flexibility of the FPC. Also, although the hole 27 is provided with only one first edge part 27a in the present example, another first edge part may be formed on the opposite side relative to the pillar-shaped projection 6, and two another second edge parts may be formed on the both sides of this another first edge part. Also, in the present example, both of the first edge part and the second edge parts are formed to be shaped like a curve. However, the shapes of holes for the present invention are not limited to such a shape, at least one of the first edge part 27a and the second edge parts 27b may be formed to have a horizontal U-shape consisting of three straight lines, for example.

In addition, in the present example, two holes and two pillar-shaped projections for fitting the FPC to the SDD are used. However, in the present invention, one hole and one pillar-shaped projection may be used depending on the size or shape of the FPC. The hole in this case may be made to have the shape of the hole 26 or the shape of the hole 27. In the case where two holes for fitting the FPC to the SDD are used as in the present example, the two holes may be made to have the same shape.

Three examples of variations of a hole into which a pillar-shaped projection is fitted and a portion around the hole are explained using FIGS. 7 to 9. The pillar-shaped projection is shown with long dashed double-short dashed line in each of FIGS. 7 to 9.

First, in an example of variations of the hole and the portion around the hole which is shown in FIG. 7, a hole 29 has the same shape as the hole 26 for the Example does. Also, a pillar-shaped projection 30 also has the same shape as the pillar-shaped projection 5 for the Example does. However, in this example of variations of the hole and the portion around the hole, a copper foil pattern 31 is formed with the hole 29 surrounded by the copper foil pattern 31. And, the copper foil pattern 31 is formed also on portions adjacent to five second edge parts 29b that are formed to be concave toward the center of the hole 29. However, the copper foil pattern 31 is not formed on portions adjacent to five first edge parts 29a that are formed to be convex toward the center of the hole 29.

Also, in an example of variations of the hole and the portion around the hole which is shown in FIG. 8, a hole 32 includes: three first edge parts formed to be convex curve toward the center of the hole 32; and three second edge parts formed to be concave curve toward the center of the hole 32, the three first edge parts and the three second edge parts being formed in succession while the three first edge parts are alternating with the three second edge parts. Also, a pillar-shaped projection 33 has the same shape as the pillar-shaped projection 5 for the E does. In addition, the area of spaces formed between the second edge parts 32b and the pillar-shaped projection 33 is larger than that of portions adjacent to the edge of the hole 32 which overlap with the pillar-shaped projection 33. And, in this example of variations of the hole and the portion around the hole, a copper foil pattern 34 is formed with the hole 32 surrounded by the copper foil pattern 34. And, the copper foil pattern 34 is formed also on parts of portions adjacent to the second edge parts 32b. However, the copper foil pattern 34 is not formed on portions adjacent to the first edge parts 32a.

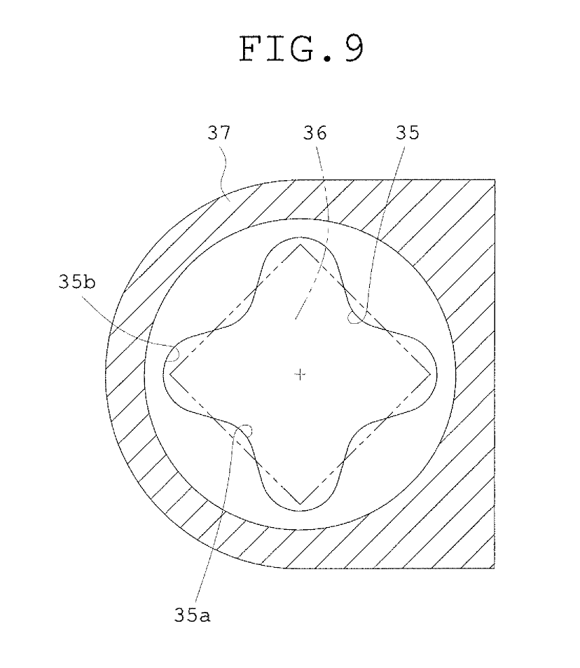

In addition, a hole 35 for an example of variations of the hole and the portion around the hole which is shown in FIG. 9 includes: four first edge parts 35a formed to be convex curve toward the center of the hole 35; and four second edge parts 35b formed to be concave curve toward the center of the hole 35, the four first edge parts 35a and the four second edge parts 35b being formed in succession while the four first edge parts 35a are alternating with the four second edge parts 35b. Also, a pillar-shaped projection 36 is shaped like a quadratic prism. In addition, the area of spaces formed between the second edge parts 35b and the pillar-shaped projection 36 is larger than that of portions adjacent to the edge of the hole 35 which overlap with the pillar-shaped projection 36. And, in this example of variations of the hole and the portion around the hole, a copper foil pattern 37 is formed with the hole 35 surrounded by the copper foil pattern 37, the copper foil pattern 37 is formed neither on the portions adjacent to the first edge parts 35a nor on the portions adjacent to the second edge parts 35b, and the copper foil patter 37 is formed at a predetermined distance from the hole 35. Besides, as seen from this example of variations of the hole and the portion around the hole, the sectional shapes of pillar-shaped projections for the present invention are not limited to circular shapes. Pillar-shaped projections for the present invention may be pillar-shaped projections having polygon-shaped sections or elliptic sections.

### Another Example

In the Example, the pillar-shaped projections 5 and 6 which are erectly provided on the base body 1 and exclusively used for fitting the FPC to the base body 1 are fitted to the FPC. On the other hand, in the Another Example, shafts are erectly provided on a shutter base plate 7 (base body) of a focal plane shutter for cameras, and the head parts of the shafts by which a shutter-driving unit, a setting unit, and so on are rotatably supported respectively are used as pillar-shaped projections as they are, for the sake of fitting of the FPC to the focal plane shutter. The constitution for the Another Example is concretely explained below, with FIGS. 10 to 15 referred to.

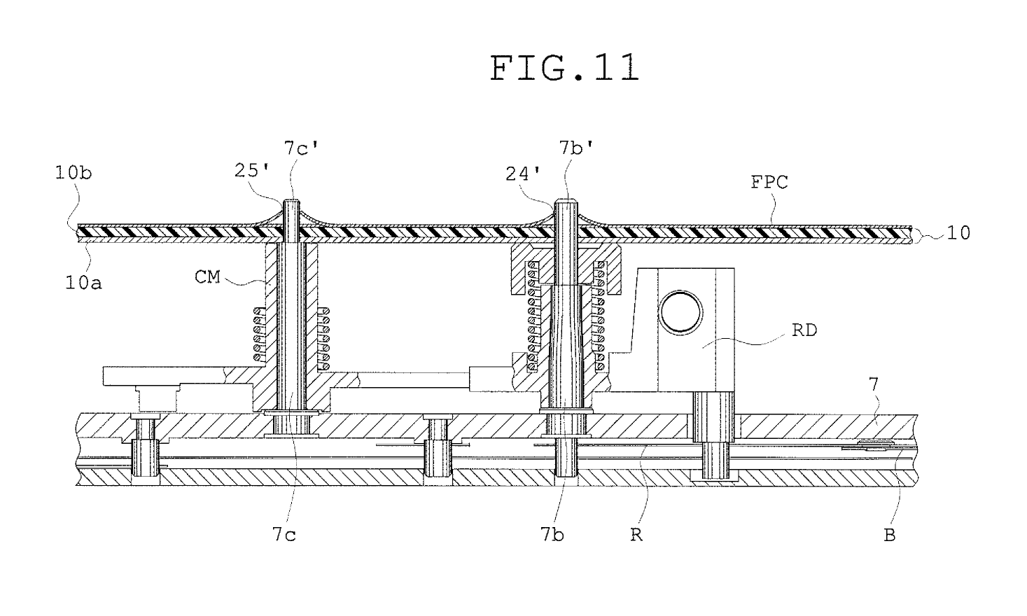

FIG. 10 is a perspective view showing a main part of the focal plane shutter FC for cameras in the case where the focal plane shutter FS for cameras shown in FIG. 1 is viewed from the right side to the left side, and FIG. 11 is a sectional view showing one example of a state in which the FPC is fitted to the head parts 7b′ and 7c′ of shafts 7b and 7c in FIG. 10.

As shown in FIG. 10, for example, pillar-shaped projections for the Another Example are the head parts 7b′, 7a′, and 7c′ of the shafts 7b, 7a, and 7c to which a second blade-driving unit

RD, a first blade-driving unit FD, and a setting unit CM are rotatably fitted respectively with the head parts 7b′, 7a′, and 7c′ protruding from the support plate 10, the second blade-driving unit RD playing a role of a rotary unit that: includes an arm R rotatably supporting a blade B and rotatably fitted to the shutter base plate 7, the blade B opening or closing an aperture O for an optical path of light from an object; and drives a second blade linked to the blade B, and the setting unit CM playing a role as a rotary unit that makes each of the driving units RD and FD operate to its setting state before shooting.

Besides, as shown in FIG. 11, a support plate 10 of the present example consists of two plates of first and second support plates 10a and 10b, the first support plate 10a is made of metal, the second support plate 10b is made of synthetic resin, and the first support plate 10a is put on the second support plate 10b while being located on the shutter-base-plate-7 side, or on the side of the second support plate 10b opposite to the flexible-print-circuit-board-FPC side, as in the Example.

As described above, in the Another Example, the head parts 7a′, 7b′, and 7c′ of the shafts 7a, 7b, and 7c are fitted into holes 24′, 24″, and 25′ of the FPC, respectively. Because the shaft 7a has almost the same structure as the shaft 7b does, FIG. 11 shows the shafts 7b and 7c. In this example, the shafts 7b and 7c and the shutter base plate 7 are made of synthetic resin while the shafts 7b and 7c are being integrated with the shutter base plate 7, and the second blade-driving unit RD and the setting unit CM are rotatably fitted to the shafts 7b and 7c, respectively. The FPC is fitted to the head parts 7b′ and 7c′ of the shafts 7b and 7c protruding from the support plate 10 via the second support plate 10b that is put on the first support plate 10a. Although the shafts 7b and 7c and the base plate 7 are made of synthetic resin and the shafts 7b and 7c are integrated with the base plate 7 in this example, these shafts 7b and 7c may be made of metal to be erectly provided on the base plate 7 through caulking method or the like, in the present invention. Alternatively, both of the shafts 7b and 7c and the base plate 7 may be made of metal to be assembled into one part.

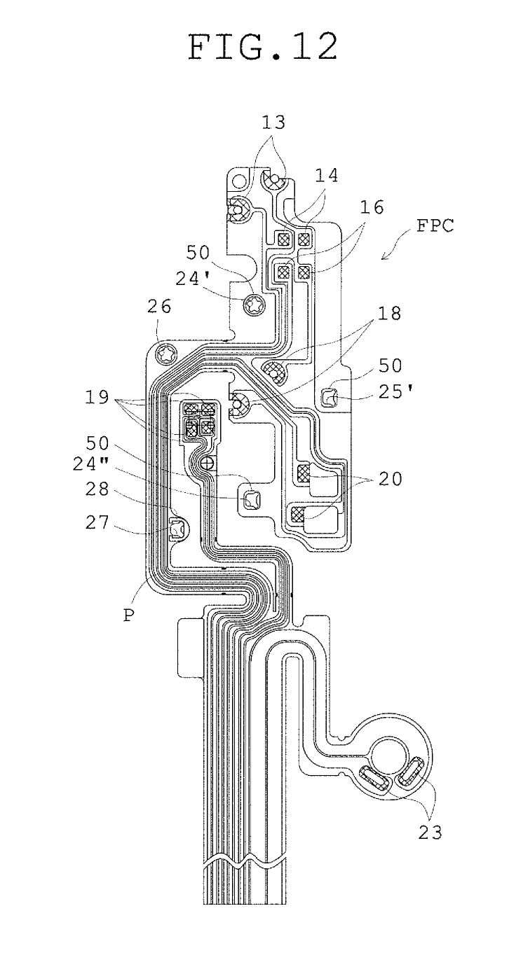

Next, the constitution of the FPC used for the Another Example is explained with FIG. 12 referred to.

The constitution matters of the FPC for the Another Example is different from those of the FPC for the Example only in the shape of the holes 24′, 24″, and 25′ and in a fact that a copper foil pattern 50 for reinforce is formed on each of portions around these holes 24′, 24″, and 25′, and the other constitution matters of the FPC for the Another Example are the same as those of the FPC for the Example. Accordingly, components and portions in the Another Example each of which is the same one as is used in the Example are given the same references as those in the Example, respectively, and the explanations of these components and portions are omitted.

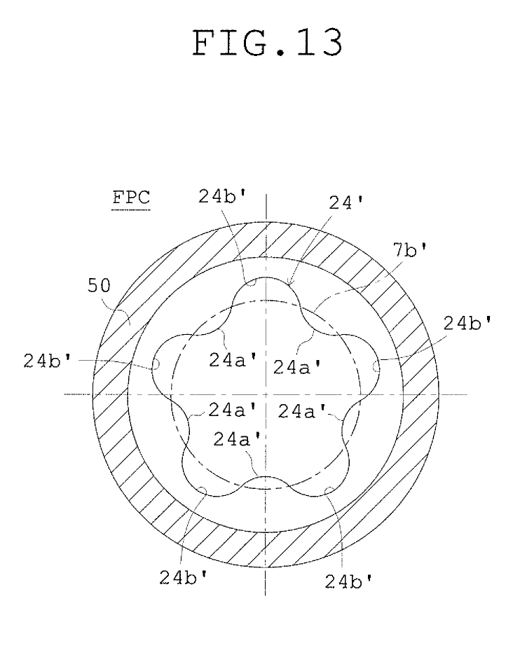

Next, three examples of variations of holes into which pillar-shaped projection or the head parts 7a′, 7b′, and 7c′ of the shafts 7a, 7b and 7c are fitted respectively and portions around the holes are explained using FIGS. 13 to 15. A pillar-shaped projection shown in each of these drawings is shown with long dashed double-short dashed line.

In an example shown in FIG. 13, the edge of a hole 24′ includes: five first edge parts 24a′ formed to be convex curve toward the center of the hole 24′; and five second edge parts 24b′ formed to be convex curve toward the center of the hole 24′, the five first edge parts 24a′ and the five second edge parts 24b′ being formed to continuously link to another ones while the five first edge parts 24a′ are alternating with the five second edge parts 24b′. And, a copper foil patterns 50 is formed on a portion around the hole 24′ at a predetermined distance from the hole 24′ while the first edge parts 24a′ and the second edge parts 24b′ are being surrounded by the copper foil patter 50.

Besides, the relation between the sizes of the hole 24′ and the head part 7b′ shown in FIG. 13, a method of fitting the head part 7b′ into the hole 24′, and operation effects with respect to this matter are the same as those explained above with FIGS. 4 and 5 referred to, and the explanations of these matters are omitted.

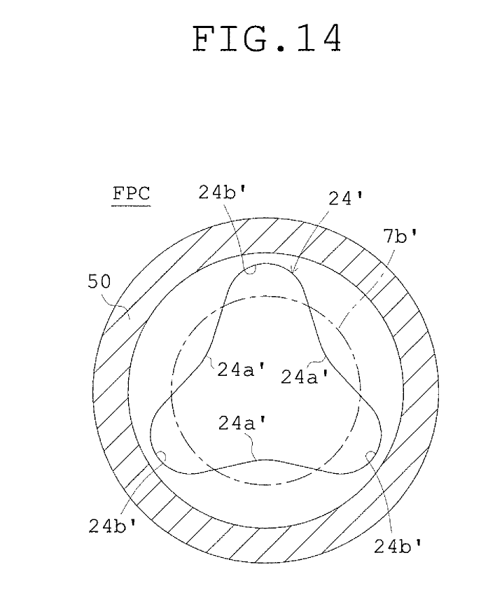

The shape of the hole 24′ shown in FIG. 14 is different from that of the hole 24′ shown in FIG. 13 in that the hole 24′ shown in FIG. 14 includes three first edge parts 24a′ and three second edge parts 24b′ which are arranged at regular intervals. Also in this case, the relation between the sizes of the hole 24′ and the head part 7b′ shown in FIG. 14, a method of the fitting part 7b′ into the hole 24′, and operation effects with respect to this matter are the same as those explained above with FIGS. 4 and 5 referred to, and the explanations of these matters are omitted.

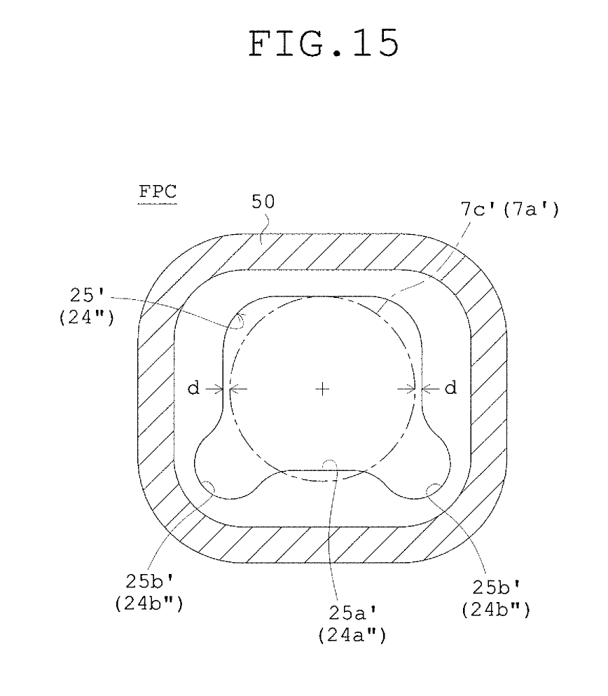

FIG. 15 shows an example of the shape of the hole similar to the shape of hole for the example shown in FIG. 6. In this example, the hole 25′ (24a″) includes first edge parts 25b′ (24b″), and spaces d are formed between the edge of the hole 25′ (24a″) and the head part 7c′ (7a′). However, the shape of a copper foil pattern 50 shown in FIG. 15 is different from that of the copper foil pattern shown in FIG. 6 in that the copper foil pattern 50 shown in FIG. 15 is formed to be a rectangular ring by which the first edge parts and a second edge part are being surrounded. However, also in the present example, the relation between the sizes of the hole and the head part 7c′ (7a′), a method of fitting the head part into the hole, and the operation effects with respect to this matter are the same ones as explained above with FIG. 6 referred to, and the explanations of these matters are omitted.

In FIGS. 10 to 15 as described above, it is explained that the head parts 7a′ and 7b′ of the shafts 7a and 7b by which the first blade-driving unit and the second blade-driving unit are rotatably supported respectively and the head part 7c′ of the shaft 7c by which the setting unit is rotatably supported are made to protrude from the support plate 10 to be used as pillar-shaped projections that are originally provided on the support plate 10. However, needles to say, the head part or the like of another shaft protruding from the support plate 10 may be used as a pillar-shaped projection.

### Yet Another Example

Next, the Yet Another Example is explained with FIGS. 16 to 20 referred to. This example is different from every above-described example in that the flexible print circuit board of the Yet Another Example is provided with a copper foil pattern: that includes holes having the same shape and the same size as the holes provided for the FPC and fitted to the pillar-shaped projection do; and that is electrically connected to the pillar-shaped projection so as to be electrically connected to the camera-body side not shown in the drawings for example. However, the holes for the Yet Another Example into which the pillar-shaped projections are fitted respectively have substantially the same shapes as the holes for the Example and Another Example do, respectively. Accordingly, components and portions for the Yet Another Example which are identical or similar to those for the Another Example respectively are given the same references as they are given in the Another Example, in FIGS. 16 to 20, and the explanations of these components and portions for the Yet Another Example are omitted.

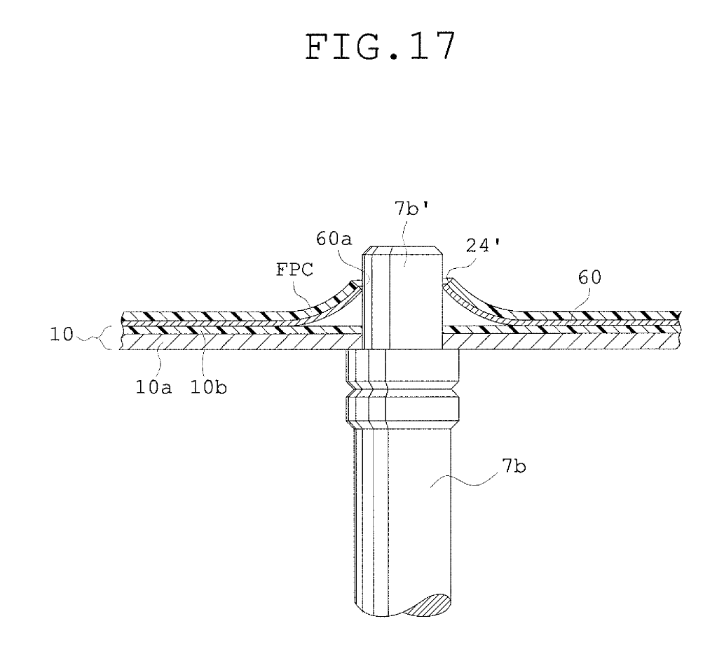

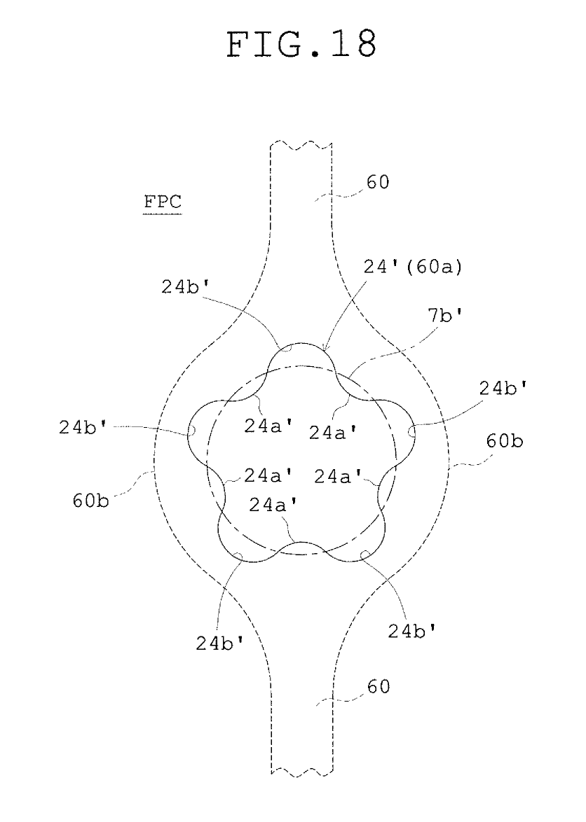

In the Yet Another Example, a support plate 10 consists of a metal plate 10a and an insulating film sheet 10b that is placed on the metal sheet 10a, as shown in FIGS. 16 and 17. In addition, as shown in FIG. 18 for example, a conductive copper foil pattern 60 which is wholly elongated and has a suitable length is provided on the back surface of the FPC, or on the insulating-film-sheet-10b side, together with the wiring pattern P, the conductive copper foil pattern 60 including: a hole 60a that has almost the same shape and almost the same size as the hole 24′ of the FPC with the first and second edge parts 24a′ and 24b′ does; and an arc-shaped exterior edge part 60b concentric with the hole 60a.

Accordingly, when the pillar-shaped projection 7b′ is fitted into the hole 24′ of the FPC and the hole 60a of the copper foil pattern 60, the inner edge of the hole 60a is electrically connected to the circumference surface of the pillar-shaped projection 7b′, as shown in FIG. 17, so that it is possible to discharge static electricity with which a device is charged through the pillar-shaped projection 7b′, by the copper foil pattern 60. That is to say, in the case where the base plate 7 is made of synthetic resin as in the Yet Another Example, it is possible to favorably discharge static electricity through the shaft 7a to the camera-body side despite the occurrence of the static electricity due to a slide of the blade B, so that it is possible to remove a failure of a device like a shutter due to static electricity with which the device is charged.

Next, the shape of the hole 24′ provided for the FPC and the relation between the hole and the pillar-shaped projection 7a′ are explained using FIGS. 18, 19, and 20.

FIG. 18 is an enlarged plane view showing the portion around the hole 24′ (60a) into which the pillar-shaped projection 7a′ is not inserted yet, and the pillar-shaped projection 7a′ is shown with long dashed short dashed line.

As shown in FIG. 18, the edge of the hole 24′ for the present example includes: five first edge parts 24a′ formed to be convex curves toward the center of the hole 24′; and five second edge parts 24b′ formed to be concave curves toward the center of the hole 24′, the five first edge parts 24a′ and the five second edge parts 24b′ being formed in succession while the five first edge parts 24a′ are alternating with the five second edge parts 24b′. When the top end of the pillar-shaped projection 7b′ is made to meet the hole 24′ in order to fit the pillar-shaped projection 7b′ into the hole 24′, portions adjacent to the first edge parts 24a′ overlap with the pillar-shaped projection 7b′. In this case, a space is formed between each of the five second edge parts 24b′ and the pillar-shaped projection 7b′. The area of the spaces between the second edge parts 24b′ and the pillar-shaped projection 7b′ is formed to be larger than that of the portions adjacent to the edge of the hole 24′ which overlap with the pillar-shaped projection 7b′.

The hole 24′ (60a) is positioned relative to the pillar-shaped projection 7b′ as shown in FIG. 18, and then a portion around the hole 24′ (60a) is pushed toward the base body by a tool or a finger, so that the pillar-shaped projection 7b′ is fitted into the hole 24′ (60a) while the first edge part 24′ is being bent toward the top end of the pillar-shaped projection 7b′. And, the portion around the hole 24′ (60a) is pushed until the FPC reaches to the base body, so that the FPC is made to reach a state of the FPC shown in FIG. 17. At this point, first edge parts of the copper foil pattern 60 closely comes into contact with the lateral surface of pillar-shaped projection 7b′, so that the FPC is in a state in which the copper foil pattern 60 is electrically connected to the pillar-shaped projection 7b.

Besides, an explanation of the case where the FPC is removed from the pillar-shaped projection 7b′ for the sake of repair or the like is omitted because the explanation is the same as that explained for the FPC shown in FIG. 4.

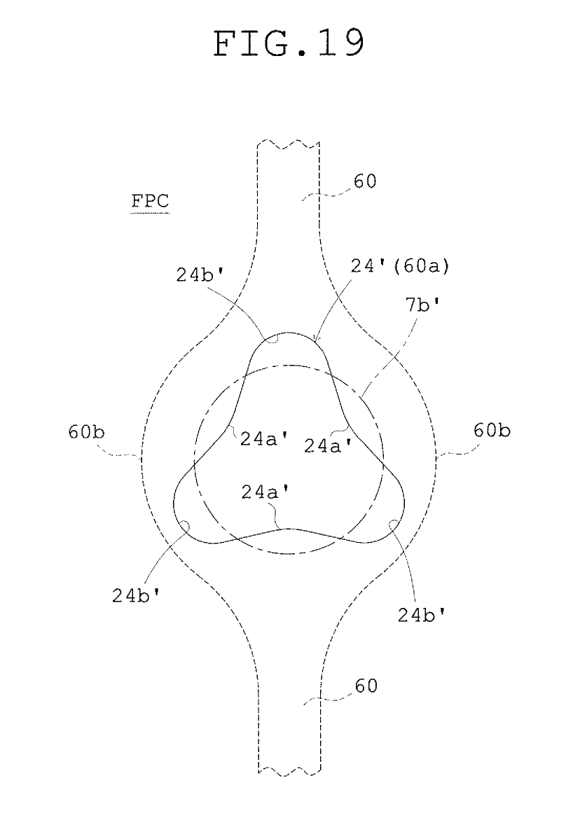

Next, the shape of the hole 24′ (60a) provided for the FPC and the relation between the hole 24′ (60a) and the pillar-shaped projection 7b′ are explained using FIG. 19. This example of variations of the hole 24′ (60a) is different from the hole 24′ (60a) shown in FIG. 18 in that the hole 24′ shown in FIG. 19 includes three first edge parts 24a′ and three second edge parts 24b′. In this example, in the case where the pillar-shaped projection 7b′ is fitted into the hole 24′ (60a), the hole 24′ (60a) shown in FIG. 19 has an advantage over the hole 24′ (60a) shown in FIG. 18 in that it is easier to fit the pillar-shaped projection 7b′ into the hole 24′ (60a) shown in FIG. 19 than to fit the pillar-shaped projection 7b′ into the hole 24′ (60a) shown in FIG. 18. However, the operation effects by the hole 24′ (60a) shown in FIG. 19 are basically the same as those by the hole 24′ (60a) shown in FIG. 18.

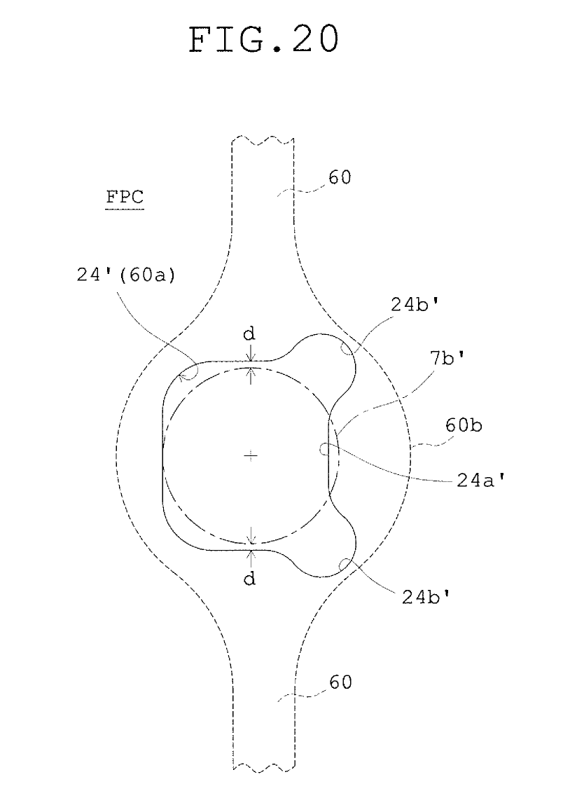

Next, the shape of the hole 24′ (60a) provided for the FPC and the relation between the hole 24′ (60a) and the pillar-shaped projection 7b′ erectly provided for the base body are explained using FIG. 20. FIG. 20 is an enlarged plane view showing the portion around the hole 24′ (60a) into which the pillar-shaped projection 7b′ is not inserted yet, and the pillar-shaped projection 7b′ is shown with long dashed short dashed line.

As shown in FIG. 20, a part of the edge of the hole 24′ (60a) for the present example includes: one first edge part 24a′ formed to be convex toward the center of the hole 24′; and two second edge parts 24b′ formed to be concave curves toward the center of the hole 24′, with the two second edge parts 24b′ located on the both sides of the first edge part 24a′ respectively. When the top end of the pillar-shaped projection 7b′ is made to meet the hole 24′ (60a) in order to fit the pillar-shaped projection 7b′ into the hole 24′ (60a), only one portion adjacent to the first edge part 24a′ overlaps with the pillar-shaped projection 7b′. On the other hand, portions adjacent to the other edge parts except for the first edge part 24a′ do not overlap with pillar-shaped projection 7b′. The area of the spaces formed between the second edge parts 24b′ and the pillar-shaped projection 7b′ is larger than that of the portion adjacent to the edge of the hole 24′ which overlaps with the pillar-shaped projection 7b′. The hole 24′ is formed to have spaces d between an edge part of the hole 24′ (60a) on the upper side of FIG. 20 and the pillar-shaped projection 7b′ and between an edge part of the hole 24′ (60a) on the lower side of FIG. 20 and the pillar-shaped projection 7b′. As a result, even though the center of the hole 24′ (60a) is somewhat out of the center of the pillar-shaped projection 7b′ due to some cause when the center of the hole 26 is made to align with the center of the pillar-shaped projection 5, the pillar-shaped projection 7b′ can be fitted into the hole 24′ (60a).

Accordingly, the hole 24a′ (60a) having such a shape is positioned relative to the pillar-shaped projection 7b′ as shown in FIG. 20, and then a portion around the hole 24′ (60a) is pushed toward the base body by a tool or a finger, so that the pillar-shaped projection 7b′ is fitted into the hole 24′ (60a) while the only one first edge part 24a′ provided for the edge of the hole 24′ is warping toward the top end of the pillar-shaped projection 7b′. The pillar-shaped projection 7b′ cannot be easily removed from the hole 24′ (60a) due to friction force between the first edge part 24a′ and the pillar-shaped projection 7b′, so that it is possible to secure electrical conduction in the FPC.

Besides, although the shaft 7b is made of synthetic resin in the present example, the shaft 7b may be made of metal. In addition, shafts and a base plate may be made of metal. Such a manner makes it possible to favorably discharge static electricity all the more.

Also, in the explanation of the present example, only the pillar-shaped projection 7b′ of the shaft 7b is fitted into the hole of the copper foil pattern 60. However, the present invention is not limited to such a constitution. Needless to say, a pillar-shaped projection of another shaft may be fitted into the hole of the copper foil pattern 60.

### Further Example

Next, the Further Example is explained using FIG. 21. The present example is the case where the present invention is applied to a blade-driving device like a diaphragm for cameras. And, FIG. 21 is a front view showing a unit of the blade-driving device. The blade-driving device IDD shown in FIG. 21 has a structure similar to that of a publically-known iris-type diaphragm that is disclosed in Japanese Patent TOKUKAI No. 2003-57715 for example. A blade room is formed between a diaphragm base plate 38 and a cover plate 39, and a driving unit not shown in the drawings and six diaphragm blades 40 are arranged in the blade room. Also, a stepping motor 41 and a sensor 42 are fitted to the diaphragm base plate 38.

The stepping motor 41 is used for rotating the above-described diaphragm-driving ring not shown in the drawing to change a size of a diaphragm aperture formed by the six diaphragm blades 40. The sensor 42 is a photo-interrupter (or a photo-reflector) and is used for detecting an initial position of the diaphragm-driving ring not shown in the drawings when the diaphragm aperture has the maximum diameter.

In the present example, a FPC is fitted to such a blade-driving device IDD. A method of fitting the FPC to the blade-driving device IDD is as follows: two pillar-shaped projection 45 and 46 which are erectly provided on the cover plate 39 (base body) are fitted into two holes 43 and 44 provided for the FPC, respectively; and then the FPC is soldered to the stepping motor 41 and the sensor 42.

In order to clearly illustrate the shapes of the two holes 43 and 44 into which the pillar-shaped projections 45 and 46 are not fitted respectively yet in FIG. 21, the actual shapes of the pillar-shaped projections 45 and 46 are not clearly illustrated in FIG. 21. The pillar-shaped projections 45 and 46 for the present example are shaped like a cylinder, like the pillar-shaped projection 5 for the Example. The holes 43 and 44 also have the same shape as the hole 26 for the Example does. In addition, copper foil patterns 47 and 48 are formed at predetermined distances from the holes 43 and 44 respectively to be shaped like a circle while the copper foil pattern 47 is concentric with the hole 43 and the copper foil patter 48 is concentric with the hole 44, in the present example. And, methods of fitting the pillar-shaped projections 45 and 46 into the holes 43 and 44 respectively are performed on the basis of the method of fitting the pillar-shaped projection 5 into the hole 26 in the Example. Accordingly, an explanation of the methods of fitting the pillar-shaped projections 45 and 46 into the holes 43 and 44 respectively is omitted. Also, the relations of the sizes of the holes 43 and 44 of the FPC to the pillar-shaped projections 45 and 46 and the operation effects in the Further Example are the same as those in the Example.

As in the above-described Example, Another Example and Yet Another Example, the FPCs are applied to focal plane shutters for cameras. However, the FPCs of the Example, Another Example and Yet Another Example are not limited to the applications to focal plane shutters for cameras. Needless to say, for example, the FPCs of the Example, Another Example and Yet Another Example may be also applied to other devices as in the Further Example. In addition, also in other devices, the head part of a support shaft to which a rotary unit is rotatably fitted may be used as a pillar-shaped projection.

1. A flexible print circuit board comprising:
a hole into which a pillar-shaped projection protruding from a base body of a device is fitted, the hole including
at least one first edge part formed to have a convex shape toward the center of the hole and
second edge parts provided on the both sides of the first edge part respectively and formed to have a concave shape toward the center of the hole.

2. The flexible print circuit board according to claim 1, wherein
the first and second edge parts of the edge of the hole are formed in succession while the first edge parts are alternating with the second edge parts.

3. The flexible print circuit board according to claim 1,
at least the second edge parts of the first and second edge parts are formed to be shaped like a curve.

4. The flexible print circuit board according to claim 1,
a copper foil pattern is formed at a predetermined distance from the edge of the hole while the hole is partially or wholly surrounded by the copper foil pattern.

5. The flexible print circuit board according to claim 4,
the copper foil pattern is formed adjacently to at least a part of the second edge parts.

6. The flexible print circuit board according to claim 1,
a copper foil pattern including a second hole is formed on a surface of the flexible print circuit board through which the flexible print circuit board is fitted to the base body, the second hole having approximately the same shape and approximately the same size as the hole of the flexible print circuit board does.

7. The flexible print circuit board according to claim 1,
a head part of a support shaft which is erectly provided for the base body and to which a rotary unit is rotatably fitted is fitted into the hole.

8. A device comprising:
a flexible print circuit board comprising:
a hole into which a pillar-shaped projection protruding from a base body of a device is fitted, the hole including
at least one first edge part formed to have a convex shape toward the center of the hole and
second edge parts provided on the both sides of the first edge part respectively and formed to have a concave shape toward the center of the hole.

9. The device according to claim 8, wherein
a copper foil pattern is formed at a predetermined distance from the edge of the hole while the hole is partially or wholly surrounded by the copper foil pattern.

10. The device according to claim 8, wherein
a head part of a support shaft which is erectly provided for the base body and to which a rotary unit is rotatably fitted is fitted into the hole.
